(19) United States
(12) Patent Application Publication
(10) Pub. No.: US 2017/0025388 A1
(43) Pub. Date: Jan. 26, 2017

(54) Backside Stacked Die In An Integrated Circuit (IC) Package

(71) Applicant: Microchip Technology Incorporated, Chandler, AZ (US)

(72) Inventors: Hazel Caballero, Gilbert, AZ (US); Fernando Chen, Gilbert, AZ (US)

(73) Assignee: Microchip Technology Incorporated, Chandler, AZ (US)

(21) Appl. No.: 15/215,743

(22) Filed: Jul. 21, 2016

Related U.S. Application Data
(60) Provisional application No. 62/195,670, filed on Jul. 22, 2015.

(51) Int. Cl. H01L 25/065; H01L 23/00; H01L 25/00; H01L 23/528

(52) U.S. Cl. CPC H01L 25/0657; H01L 23/5286; H01L 24/73; H01L 25/50; H01L 2225/0651; H01L 2225/0652; H01L 2225/06551; H01L 2225/06572; H01L 2225/06555; H01L 2224/73265

(57) ABSTRACT

An integrated circuit (IC) device may include a substrate including a first mounting area and a ground ring, a first integrated circuit die attached to the first mounting area, a die attach paddle mounted onto the ground ring and extending above the first integrated circuit die, and a second integrated circuit die mounted on a second mounting area, wherein the die attach paddle defines the second mounting area above the first integrated circuit die. The second integrated circuit die may have a backside oriented toward the substrate and connected to ground.

### RELATED PATENT APPLICATION

This application claims priority to commonly owned U.S. Provisional Patent Application No. 62/195,670, filed Jul. 22, 2015, the entire contents of which are hereby incorporated by reference herein for all purposes.

### TECHNICAL FIELD

The present disclosure relates to semiconductor manufacturing technology, in particular to a manufacturing method for providing multiple electrically active dies in a single IC package, e.g., by providing a backside stacking of one or more dies in an IC package.

### BACKGROUND

In semiconductor manufacturing, multiple integrated circuit (IC) dies may be mounted to a common substrate. The footprint of each die may be important as the size requirements for IC devices are shrinking at the same time processing requirements are increasing. Redesigning a IC die/chip to increase performance and maintain or reduce footprint likely requires a new chip design, tooling a new mask, and/or additional costs and requirements.

### SUMMARY

One embodiment provides an integrated circuit (IC) device comprising: a substrate including a first mounting area and a ground ring, a first integrated circuit die attached to the first mounting area, a die attach paddle mounted onto the ground ring and extending above the first integrated circuit die, and a second integrated circuit die mounted on a second mounting area, wherein the die attach paddle defines the second mounting area above the first integrated circuit die.

In one embodiment, the second integrated circuit die includes a backside oriented toward the substrate and connected to ground.

In one embodiment, the IC deice further comprises a conductive die attach material joining the die attach paddle to the substrate.

In one embodiment, the first integrated circuit die and the second integrated circuit die have matching footprints.

In one embodiment, the first integrated circuit die and the second integrated circuit die comprise identical devices.

In one embodiment, the first integrated circuit die and the second integrated circuit die comprise 4-channel pulsers.

In one embodiment, the first mounting area comprises an exposed die attach pad.

In one embodiment, leads of the first and second integrated circuit dies are connected to the substrate using wirebond.

In one embodiment, the die attach paddle is attached to the ground ring with a copper clip.

Another embodiment provides a method for manufacturing a stacked integrated circuit device, the method comprising: attaching a first die to a substrate having an exposed die attach pad, connecting an external die attach paddle to the substrate, the external die attach paddle extending over the first die, and attaching a second die to the external die attach paddle.

In one embodiment, the method further includes connecting leads of the first die to leads of the substrate by wire bonding.

In one embodiment, the method further includes connecting leads of the second die to leads of the substrate by wire bonding.

In one embodiment, the method further includes attaching the first and second dies using conductive die attach material.

In one embodiment, the external die attach paddle provides a backside connection to ground for the second die.

In one embodiment, connecting an external die attach paddle to the substrate includes using conductive die attach material.

In one embodiment, the first and second dies comprise matching integrated circuit devices.

In one embodiment, the first and second dies comprise 4-channel pulsers.

In one embodiment, the first and second dies have matching footprints.

Another embodiment provides an 8-channel pulser comprising: a substrate including a first mounting area and a ground ring, a first 4-channel pulser attached to the first mounting area, and a die attach paddle mounted onto the ground ring and extending above the first 4-channel pulser, and a second 4-channel pulser mounted on a second mounting area, wherein the die attach paddle defines the second mounting area above the first 4-channel pulser.

In one embodiment, the 8-channel pulser further includes a backside of the second 4-channel pulser connected to ground through the die attach paddle.

### BRIEF DESCRIPTION OF THE DRAWINGS

FIG. 1 is a drawing illustrating a side view of an example integrated circuit device according to teachings of the present disclosure; and

FIG. 2 is a flowchart illustrating an example method according to teachings of the present disclosure.

### DETAILED DESCRIPTION

Although stacking IC dies may provide a reduced total footprint, known methods for stacking do not provide a ground connection for the backside of the upper or top die. In some embodiments of the present teaching, a copper clip may be mounted on top of a first die (the bottom die) and then used as a die attach paddle for the top die.

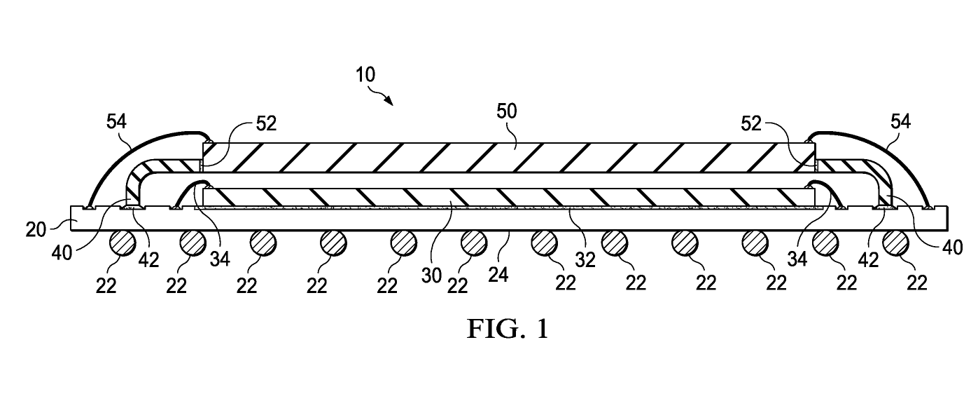

FIG. 1 is a drawing illustrating a side view of an example integrated circuit device 10 according to teachings of the present disclosure. Integrated circuit device 10 may include a substrate 20, a first IC die 30, an external die attach paddle 40, and a second IC die 50. In this embodiment, the backside of both first IC die 30 (on the bottom) and second IC die 50 (on the top) are ground connected.

As shown, substrate 20 may include solder balls 22 and an exposed die attach pad 24. Substrate 20 may comprise any appropriate material (e.g., silicon or other semiconductor). In some embodiments, substrate 20 may include features arranged to mate with a socket or other mounting apparatus deployed on a printed circuit board (PCB). Exposed die attach pad 24 may have any features appropriate for mounting an IC die thereon, including exposed leads, a thermal/heat sink pad, etc. In some embodiments, substrate 20 may include alternative features for attaching an IC die. The substrate design may include exposed die attach pad 24 with a soldermask mesh design.

First IC die 30 may be attached to the substrate 20 (e.g., attached to the exposed die attach pad 24). IC die 30 may comprise a set of electronic circuits on a plate of semiconductor material (e.g., silicon). IC die 30 may be any size, shape, or useful configuration. In some embodiments, such as that shown in FIG. 1, first IC die 30 may be attached to the substrate with die attach material 32. Die attach material 32 may be a conductive material (e.g., a paste or a film) providing both electrical and mechanical connection between first IC die 30 and exposed die attach pad 24 or the other features of substrate 20. In some embodiments, various leads of first IC die 30 may be connected to leads on substrate 20 and/or die attach pad 24 by wire bonding. As shown in FIG. 1, bond wires 34 provide electrical connection between first IC die 30 and leads on substrate 20. In some embodiments, IC die 30 may comprise a 4-channel pulser.

External die attach paddle 40 may comprise any apparatus or device appropriate for attachment to the substrate 20 and providing a mount for the second IC die 50. In some embodiments, external die attach paddle 40 comprises a copper clip. In these embodiments, the copper clip is connected to various feature of substrate 20 and attached using die attach material 42 (e.g., conductive paste or film), then the second IC die 50 is placed on the copper clip and attached using die attach material 52 (e.g., conductive paste/film). Substrate 20 may include a ground ring to serve as pad for a copper clip to establish the multi-layer die attach pad.

As shown in FIG. 1, the external die attach paddle 40 provides a second die attach pad allowing a stacked die package. The external die attach paddle 40 provide this additional layer of die attach pad allowing the top die (second IC die 50) to be grounded at its backside. Die attach material 42 attaches the external die attach paddle 40 to the substrate. In some embodiments, a conductive die attach material 42 provides a ground connection to both the top and bottom die.

Second IC die 50 may be attached to the external die attach paddle 40 (e.g., attached to an exposed die attach pad disposed thereon). IC die 50 may comprise a set of electronic circuits on a plate of semiconductor material (e.g., silicon). IC die 50 may be any size, shape, or useful configuration. In some embodiments, such as that shown in FIG. 1, second IC die 50 may be attached to the external die paddle 40 with die attach material 52. Die attach material 52 may be a conductive material (e.g., a paste or a film) providing both electrical and mechanical connection between second IC die 50 and external die attach paddle 40 or the features thereon. In some embodiments, various leads of second IC die 50 may be connected to leads on substrate 20 and/or die attach pad 24 by wire bonding. As shown in FIG. 1, bond wires 54 provide electrical connection between second IC die 50 and leads on substrate 20. In some embodiments, IC die 50 may comprise a 4-channel pulser.

In some embodiments, the two IC dies 30, 50 may have similar or identical function and form. Integrated circuit device 10 may provide, for example, two stacked IC dies 30, 50 each comprising a four-channel feature of any type of functionality (e.g., driver, pulser, etc.). The stacked formation incorporating teachings of the present disclosure may provide a IC device 10 with the same footprint as the four-channel device, but with 8-channel function. Instead of designing a completely new integrated circuit or doubling the required footprint, these teachings may be used to integrate two existing integrated circuit dies in a single package and wire them internally to provide for their respective functionality in a single device.

For example, a certain integrated circuit device may be currently offered in a 64L QFN 9×9 mm package. There may be a demand for the same functionality with twice the number of devices or channels. Rather than employing a new design for the desired device, for example an eight-channel pulser, a double stack of the original IC device may offer two four-channel pulser dies in one package, delivering an eight-channel pulser in a smaller package and without a new IC design.

In a stacked configuration according to the teachings of the present disclosure, the footprint of the device is not enlarged. In addition, the ground connection provided by the external die attach paddle 40 may be required for certain standards and/or applications (e.g., SOI wafers). A side-by-side solution may satisfy the grounding requirement, but the package size will be at least 60% larger compared to the stacked die solution described herein. Thus, in some embodiments, the multi-layer external die attach paddle 40 allows for an arrangement of multiple dies above each other while still providing ground connection for each die in order to achieve the reduced package size without redesigning the die and/or tooling a new mask set.

These teachings can be employed with additional types of IC housings incorporating a support structure allowing for placement of an external die attach paddle as shown in FIG. 1. For example, a leadframe design may provide an area onto which such a paddle can be attached. The stack may be extended to more than two semiconductor dies. In embodiments including a U-shaped die attach paddle, two U-shaped die attach paddles 40 may be arranged above each other in a 90 degree configuration.

As previously noted, the first 30 and second 50 integrated circuit dies can be identical. However, other embodiments may integrate two different integrated circuit dies within a single package. The two integrated circuit devices may have different sizes, wherein preferably the smaller die is arranged on top of the larger die.

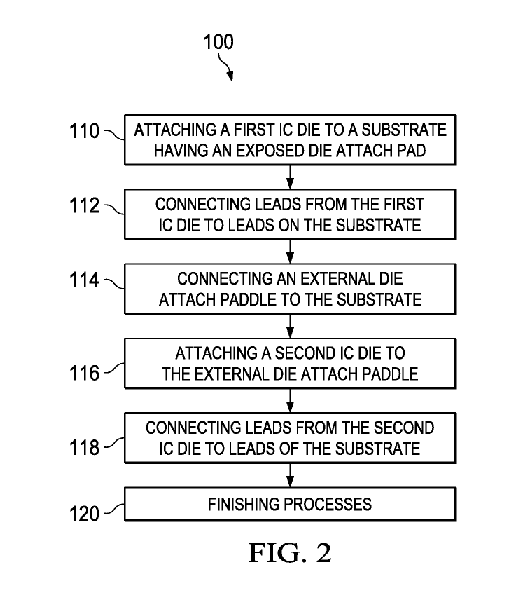

FIG. 2 is a flowchart illustrating an example method 100 for manufacturing a stacked integrated circuit device according to teachings of the present disclosure. Method 100 may comprise any of the following steps, performed in any suitable order.

Step 110 may include attaching a first IC die 30 to a substrate 20 having an exposed die attach pad 24. The first IC die 30 may be attached using die attach material 32, e.g., a conductive film and/or paste, as described above.

Step 112 may include connecting leads from the first IC die 30 to leads on the substrate. In some embodiments, this may include wire bonding.

Step 114 may include connecting an external die attach paddle 40 to the substrate 20. The external die attach paddle 40 may extend over the first die. The external die attach paddle 40 may be attached using die attach material 42, e.g., a conductive film and/or paste, as described above.

Step 116 may include attaching a second IC die 50 to the external die attach paddle 40. The second IC die 50 may be attached using die attach material 52, e.g., a conductive paste and/or film. In embodiments including this step, the connection of second IC die 50 to the external die attach paddle 40 may provide a backside connection to ground (on the substrate) for the second IC die 50.

Step 118 may include connecting leads from the second IC die 50 to leads of the substrate 20. In some embodiments, this step may include wire bonding.

Method 100 may include any finishing processes known in the manufacture of semiconductors and/or IC devices. For example, standard end of line assembly processes such as mold, marking, and singulation may follow Step 118.

As described in relation to FIG. 1, the first 30 and second die 50 may comprise matching integrated circuit devices. According to the teachings of the present disclosure, matching IC devices may have similar footprints and/or function, etc. For example, in some embodiments, the first and second die are both 4-channel pulsers, providing the function of an 8-channel pulser in the same footprint that previously held a single 4-channel pulser, with the burden of redesigning the IC circuit or retooling the manufacturing process.

1. An integrated circuit device comprising:
a substrate including a first mounting area and a ground ring;
a first integrated circuit die attached to the first mounting area;
a die attach paddle mounted onto the ground ring and extending above the first integrated circuit die; and
a second integrated circuit die mounted on a second mounting area;
wherein the die attach paddle defines the second mounting area above the first integrated circuit die.

2. An integrated circuit device according to claim 1, wherein the second integrated circuit die includes a backside oriented toward the substrate and connected to ground.

3. An integrated circuit device according to claim 1, further comprising a conductive die attach material joining the die attach paddle to the substrate.

4. An integrated circuit device according to claim 1, wherein the first integrated circuit die and the second integrated circuit die have matching footprints.

5. An integrated circuit device according to claim 1, wherein the first integrated circuit die and the second integrated circuit die comprise identical devices.

6. An integrated circuit device according to claim 1, wherein the first integrated circuit die and the second integrated circuit die comprise 4-channel pulsers.

7. An integrated circuit device according to claim 1, wherein the first mounting area comprises an exposed die attach pad.

8. An integrated circuit device according to claim 1, wherein leads of the first and second integrated circuit dies are connected to the substrate using wirebond.

9. An integrated circuit device according to claim 1, wherein the die attach paddle is attached to the ground ring with a copper clip.

10. A method for manufacturing a stacked integrated circuit device, the method comprising:
attaching a first die to a substrate having an exposed die attach pad;
connecting an external die attach paddle to the substrate, the external die attach paddle extending over the first die;
attaching a second die to the external die attach paddle.

11. A method according to claim 10, further comprising connecting leads of the first die to leads of the substrate by wire bonding.

12. A method according to claim 10, further comprising connecting leads of the second die to leads of the substrate by wire bonding.

13. A method according to claim 10, further comprising attaching the first and second dies using conductive die attach material.

14. A method according to claim 10, wherein the external die attach paddle provides a backside connection to ground for the second die.

15. A method according to claim 10, wherein connecting an external die attach paddle to the substrate includes using conductive die attach material.

16. A method according to claim 10, wherein the first and second die comprise matching integrated circuit devices.

17. A method according to claim 10, wherein the first and second dies comprise 4-channel pulsers.

18. A method according to claim 10, wherein the first and second dies have matching footprints.

19. An 8-channel pulser, comprising:
a substrate including a first mounting area and a ground ring;
a first 4-channel pulser attached to the first mounting area; and
a die attach paddle mounted onto the ground ring and extending above the first 4-channel pulser; and
a second 4-channel pulser mounted on a second mounting area;
wherein the die attach paddle defines the second mounting area above the first 4-channel pulser.

20. An 8-channel pulser according to claim 19, further comprising a backside of the second 4-channel pulser connected to ground through the die attach paddle.
